(19) United States
(12) Patent Application Publication
(10) Pub. No.: US 2026/0130105 A1
(43) Pub. Date: May 7, 2026

(54) Film Manufacturing Method, Laminated Structure, and Bolometer

(71) Applicant: NEC Corporation, Minato-ku, Tokyo (JP)

(72) Inventor: Noriyuki TONOUCHI, Tokyo (JP)

(73) Assignee: NEC Corporation, Minato-ku, Tokyo (JP)

(21) Appl. No.: 18/939,617

(22) Filed: Nov. 7, 2024

(30) Foreign Application Priority Data
Nov. 29, 2023 (JP) 2023-201758

(51) Int. Cl. H10K 85/20; G01J 5/20; G06T 5/40; G06T 5/50; G06T 5/70; G06T 7/00

(52) U.S. Cl. CPC H10K 85/221; G01J 5/20; G06T 5/40; G06T 5/50; G06T 5/70; G06T 7/0006; G06T 7/97; G06T 2207/10056; G06T 2207/20182; G06T 2207/20216; G06T 2207/30148

(57) ABSTRACT

A film manufacturing method includes forming a first self-organized film on a substrate, drying the formed first self-organized film, immersing the dried first self-organized film in a dissolving solution in which a silane coupling agent is dissolved to form a second self-organized film, drying the formed second self-organized film, and laminating a nanocarbon layer on the dried second self-organized film.

### CROSS-REFERENCE TO RELATED APPLICATION

Priority is claimed on Japanese Patent Application No. 2023-201758, filed Nov. 29, 2023, the content of which is incorporated herein by reference.

### BACKGROUND ART

This disclosure relates to a film manufacturing method, a laminated structure, and a bolometer.

It is known that carbon nanotubes are used in electrical elements.

For example, PCT International Publication No. WO/2006/103872 (hereinafter referred to as Patent Document 1) discloses a carbon nanotube field effect transistor (FET) that uses carbon nanotubes.

### SUMMARY

The carbon nanotube FET disclosed in Patent Document 1 is configured such that a substrate surface is treated with aminosilane to fix the carbon nanotubes, and amino groups are introduced onto the substrate surface. Carbon nanotube films formed using amino groups tend to have localized alignment, making it difficult to control the degree of alignment of the carbon nanotubes.

An example object of this disclosure is to provide a film manufacturing method, a laminated structure, and a borometer for solving the above-mentioned problems.

A film manufacturing method of the present disclosure includes forming a first self-organized film on a substrate, drying the formed first self-organized film, immersing the dried first self-organized film in a dissolving solution in which a silane coupling agent is dissolved to form a second self-organized film, drying the formed second self-organized film, and laminating a nanocarbon layer on the dried second self-organized film.

A laminated structure of the present disclosure includes, in order, a substrate, a self-organized film, and a nanocarbon layer having an alignment parameter, in which the alignment parameter has an alignment component and a random component, a function of the alignment component is expressed by a formula:

$${S}_{2 D}^{a l i g n} ( d ) = {S}_{full} + ( 1 - {S}_{full} ) {e}^{- \frac{d}{2 {λ}_{c}}} ,$$

wherein λ_{c} is a damping constant related to the degree of local alignment, d is a size of one side of a square observation area of the nanocarbon layer, and S_{full} is a constant value, and the damping constant is 300 nm or more.

### BRIEF DESCRIPTION OF THE DRAWINGS

FIG. 1 is a cross-sectional view I showing an example of a configuration of a laminated structure in this disclosure.

FIG. 2 is a diagram for deriving a damping constant of the laminated structure in this disclosure.

FIG. 3 is a flowchart for deriving a damping constant of the laminated structure in this disclosure.

FIG. 4 shows image processing I for deriving a damping constant of the laminated structure in this disclosure.

FIG. 5 shows image processing II for deriving a damping constant of the laminated structure in this disclosure.

FIG. 6 shows image processing III for deriving a damping constant of the laminated structure in this disclosure.

FIG. 7 shows image processing IV for deriving a damping constant of the laminated structure in this disclosure.

FIG. 8 shows image processing V for deriving a damping constant of the laminated structure in this disclosure.

FIG. 9 shows image processing VI for deriving a damping constant of the laminated structure in this disclosure.

FIG. 10 is a flowchart I showing an example of processing of a film manufacturing method in this disclosure.

FIG. 11 is a diagram showing an example of a manufacturing procedure of the film manufacturing method in this disclosure.

FIG. 12 is a cross-sectional view showing an example of a configuration of a borometer in this disclosure.

FIG. 13 is a cross-sectional view II showing an example of a configuration of a laminated structure in this disclosure.

FIG. 14 is a flowchart II showing an example of processing of the film manufacturing method in this disclosure.

FIG. 15 is a plan view of an element in an example.

FIG. 16 is a diagram showing evaluation results of a laminated structure of an element I in the example.

FIG. 17 is a SEM image showing a part of a planar image of the laminated structure of the element I in the example.

FIG. 18 is a diagram showing evaluation results of a laminated structure of an element II in the example.

FIG. 19 is a SEM image showing a part of a planar image of the laminated structure of the element II in the example.

FIG. 20 is a diagram showing evaluation results of a laminated structure of an element III in the example.

FIG. 21 is a SEM image showing a part of a planar image of the laminated structure of the element III in the example.

FIG. 22 is a diagram showing evaluation results of a laminated structure of an element IV in the example.

FIG. 23 is a SEM image showing a part of a planar image of a laminated structure of an element V in the example.

FIG. 24 is a diagram showing a relationship between the concentration of each dissolving solution 2β and a damping constant λc in a laminated structure of an element in the example.

FIG. 25 is a table showing a resistance value of a nanocarbon layer with respect to the concentration of each dissolving solution 2β in the laminated structure of the element in the example.

### EXAMPLE EMBODIMENT

Example embodiments of this disclosure will be described below with reference to the drawings. The drawings and specific configurations used in the example embodiments should not be used to interpret the disclosure. The same or equivalent configurations in all drawings will be given the same reference numerals, and common descriptions will be omitted.

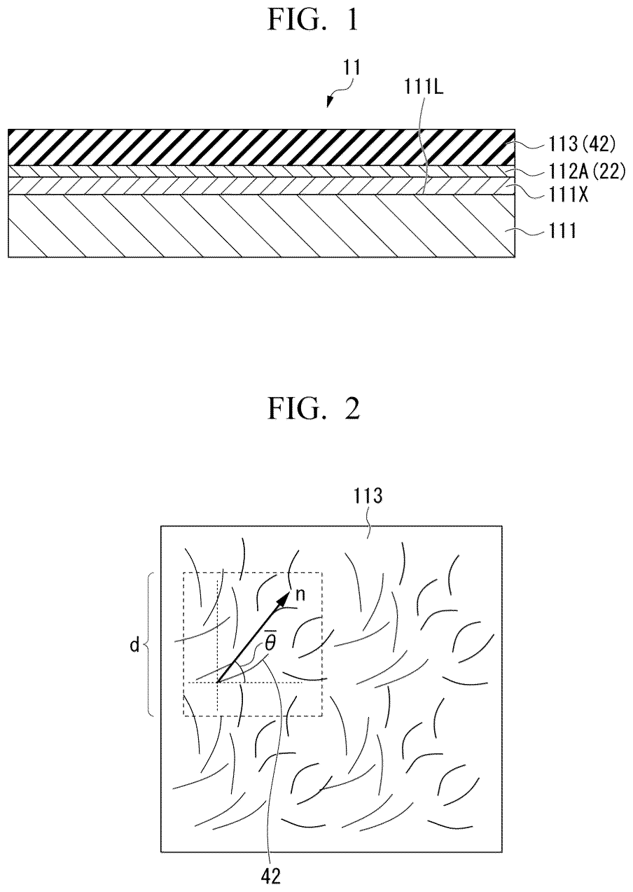

In this disclosure, the drawings relate to one or more example embodiments. Hereinafter, an example of a configuration of a laminated structure according to this disclosure will be described with reference to FIGS. 1 to 11.

### (Configuration of Laminated Structure)

For example, a laminated structure 11 is included in elements such as a borometer or a thin-film transistor.

As shown in FIG. 1, the laminated structure 11 includes a substrate 111, a self-organized film 112A, and a nanocarbon layer 113 in this order.

For example, the laminated structure 11 may include the self-organized film 112A on a lamination surface 111L of a substrate 111.

For example, the substrate 111 is a Si substrate processed using a silicon wafer.

For example, the substrate 111 may be a monomer such as Parylene (registered trademark), a resin such as polyimide, or an organic material such as plastic.

For example, a read-out circuit may be formed on the substrate 111.

For example, the substrate 111 may have an electrically insulating base insulating layer 111X. Methods of forming the base insulating layer 111X include a method of performing heat treatment on the substrate 111, and a method of directly forming the base insulating layer 111X by a chemical vapor deposition (CVD) method. The base insulating layer 111X is made of, for example, silicon oxide, silicon nitride, or the like.

For example, in this disclosure, the substrate 111 is a Si substrate having the base insulating layer 111X. Further, in this disclosure, the base insulating layer 111X is made of silicon oxide.

### (Self-Organized Film)

The self-organized film 112A contains a silane coupling agent 22 for forming the nanocarbon layer 113 on the substrate 111.

For example, an operator may use the silane coupling agent 22 having an amino group to improve the adhesion of CNTs 42 to be described below. Examples of the silane coupling agent 22 include 3-aminopropyltriethoxysilane (APTES), 3-aminopropyltrimethoxysilane, 3-aminopropylmethyltriethoxysilane, 3-aminopropylmethyltrimethoxysilane, and the like.

The amount of the self-organized film 112A is controlled by adjusting the concentration of a dissolving solution 2β to be described below. Thereby, the degree of local alignment of the nanocarbons contained in the nanocarbon layer 113 is suppressed. The degree of alignment represents the degree of alignment of the nanocarbons.

### (Nanocarbon Layer)

The nanocarbon layer 113 is laminated on the substrate 111 via the self-organized film 112A.

For example, the nanocarbon layer 113 can act as an infrared light receiving part.

The nanocarbon layer 113 contains nanocarbons.

For example, the nanocarbons form a network within the nanocarbon layer 113.

A nanocarbon refers to a nano-sized carbon material whose main component is carbon, such as a carbon nanotube (CNT), a carbon nanohorn (CNHs), carbon nanohorns (CNHs) that are an assembly of carbon nanohorns, a carbon nanobrush (CNB), a carbon nanotwist, graphene, or fullerene.

For example, in this disclosure, the nanocarbon layer 113 contains CNTs 42.

In this disclosure, the nanocarbon layer 113 has a CNT network in which the CNTs 42 are randomly aligned to form a network with each other.

The CNT 42 is a fibrous material with a diameter of 0.6 nm to 1.5 nm and a length of 100 nm to 5.0 μm. The properties of the CNT 42 change depending on the arrangement of six-membered rings in the circumferential direction.

In the CNTs 42, a cylindrical CNT made from a single graphene sheet is referred to as a single-walled CNT, and a CNT in which a plurality of CNTs with different diameters coaxially overlap each other to form a plurality of layers is referred to as a multi-walled CNT. A CNT formed as a two-layer structure is referred to as a double-walled CNT.

For example, the CNT 42 may be any of a single-walled CNT, a double-walled CNT, or a multi-walled CNT.

For example, the CNT 42 in this disclosure is a single-walled CNT.

There are two types of CNTs, that is, a semiconducting type that exhibits semiconducting properties, and a metallic type that exhibits metallic properties. Single-walled CNTs usually contain semiconducting CNTs and metallic CNTs in a 2:1 ratio. For this reason, in a case of using a large number of CNTs that exhibit one type of property are used, a separation process is necessary.

For example, the nanocarbon layer 113 may contain a mixture of semiconducting CNTs and metallic CNTs.

The plurality of CNTs 42 may contain a mixture of semiconducting CNTs and metallic CNTs. For example, the CNTs 42 may be subjected to a step of separating the semiconducting CNTs from the plurality of CNTs 42, and contain 90% or more of the total semiconducting CNTs. For example, the entire CNTs 42 may contain 92% or more of the semiconducting CNTs after the separation step. For example, the entire CNTs 42 may contain 94% or more of the semiconducting CNTs after the separation step. For example, the CNTs 42 may contain 96% or more of the total semiconducting CNTs after the separation step. For example, the CNTs 42 may contain 98% or more of the total semiconducting CNTs after the separation step.

A damping constant λ_{c}, which will be described below, is related to the degree of local alignment of the nanocarbon layer 113. For example, the damping constant λ_{c} can be used as an index that indicates the degree of alignment of the CNT network of the CNTs 42 contained in the nanocarbon layer 113.

Out of an alignment component and a random component included in an alignment parameter to be described below, the alignment component is expressed by Formula (3), which is a function of the damping constant λ_{c}, the size d of one side of a square observation area of the nanocarbon layer, and a constant value S_{full}.

$${S}_{2 D}^{a l i g n} ( d ) = {S}_{full} + ( 1 - {S}_{full} ) {e}^{- \frac{d}{2 {λ}_{c}}} \qquad ( 3 )$$

For example, the damping constant λ of the nanocarbon layer 113 is 300 nm or more.

The alignment component asymptotically approaches the constant value S_{full} as the observation area becomes larger.

### (Index of Degree of Alignment: Damping Constant)

The degree of alignment of the nanocarbon layer 113 is confirmed as follows.

In this disclosure, the alignment angle of each aligned object is calculated in units of a pixel, and the degree of alignment is evaluated using an alignment parameter S_{2D}(d) (Formula (1)), which represents the alignment order within the square observation area. The alignment parameter S_{2D}(d) (Formula (1)) is a quantity that takes values between 0 and 1.

In the following description, it is assumed that an aligned object indicates the CNT 42.

$${S}_{2 D} ( d ) = 2 \frac{{\int }_{- π / 2}^{π / 2} f ( {θ}^{′} ) {cos}^{2} ( {θ}^{′} - \overline{θ} ) d {θ}^{′}}{{\int }_{- π / 2}^{π / 2} f ( {θ}^{′} ) d {θ}^{′}} - 1 \qquad ( 1 )$$

In Formula (1), d is the size of one side of the square observation area, f(θ)′ is the frequency of an angle θ′ within the observation area with the size d, and θ⁻ is an average angle within the observation area. FIG. 2 is shown as a supplementary drawing.

In the nanocarbon layer 113 having a CNT network which is an aligned object, aligned objects that are aligned and aligned objects that are randomly aligned coexist. Then, Formula (1) can be written as Formula (2).

$${S}_{2 D}^{i m a g e} ( d ) = a {S}_{2 D}^{align} ( d ) + ( 1 - a ) {S}_{2 D}^{r a n d} ( d ) \qquad ( 2 )$$

In Formula (2), a left side is an alignment parameter, a first term on a right side is an alignment component that indicates the alignment of an aligned object, and a second term on the right side is a random component that indicates the random alignment of the aligned object. The alignment parameter can be written as the sum of two components, that is, the alignment component and the random component. In Formula (2), “a” takes a value between 0 and 1 and indicates the ratio between the alignment component and the random component.

The random component is an alignment parameter value obtained by simulation calculation in the nanocarbon layer 113 in which the lengths, directions, and positions of CNTs are randomly arranged, on the basis of the lengths and density information of CNTs in the observation area.

In a case where an aligned object, which is the CNT 42, is captured in the observation area, it can be expressed as a fibrous two-dimensional structure, and it is known that the alignment component exhibits an asymptotic damping action with respect to d, as shown in Formula (3).

$${S}_{2 D}^{a l i g n} ( d ) = {S}_{full} + ( 1 - {S}_{full} ) {e}^{- \frac{d}{2 {λ}_{c}}} \qquad ( 3 )$$

In Formula (3), when “d”, which is the length of one side of the observation area, is small, that is, in a case where the observation area is small, the alignment component takes a value close to 1. On the other hand, as “d” increases, that is, as the observation area for evaluating an alignment angle becomes larger, the alignment component exponentially attenuates due to the damping constant λ_{c} and asymptotically approaches the constant value S_{full}. Since the damping constant λ_{c} is considered to be a quantity that describes the alignment state of the network of the nanocarbon layer 113, in this disclosure, the damping constant λ_{c} included in the alignment component in the alignment parameter is used as a quantitative indicator of the degree of alignment.

### (Image Processing for Determining Damping Constant)

The overall flow is that an operator obtains alignment components from images captured by an imaging device, repeats this processing in each observation area, and then obtains a damping constant λ_{c} from each alignment component to evaluate the degree of alignment of the nanocarbon layer 113.

For example, the imaging device may be equipped with an atomic force microscope (AFM), a scanning electron microscope (SEM), a transmission electron microscope (TEM), or the like, and may be capable of capturing microscopic images of a nanocarbon network formed in the nanocarbon layer 113 and individual nanocarbons contained in the network.

For example, in this disclosure, the imaging device is assumed to include an AFM capable of imaging the CNT network of the nanocarbon layer 113 and individual CNTs 42.

To evaluate the degree of alignment of the nanocarbon layer 113, it is desirable to image an observation area with d as large as possible so that there are a plurality of areas with a specific alignment direction (also referred to as “local alignment domains”) within the observation area. In addition, it is desirable to gradually expand the observation area and observe it up to an area where the alignment component asymptotically approaches a constant value. This is because the alignment component asymptotically approaches a constant value S_{full} as the observation area becomes larger.

For example, in FIGS. 16, 18, 20, and 22 to be described below, it is desirable to include the observation area up to an area where “the value of the alignment component is 0.2” or less and it can be confirmed that the alignment component (S_fit) asymptotically approaches a constant value (S_{full}). In the observation area where it can be confirmed that the alignment component asymptotically approaches the constant value (S_{full}), it is observed that the alignment of the aligned object changes from a state where it is aligned in one direction (a state where d is small) to a state where the alignment becomes random to a certain extent.

On the other hand, in the observation area where it has not been confirmed that the alignment component asymptotically approaches the constant value (S_{full}) (each observation area where exponential attenuation is observed at d<2000 nm), it is observed that the nanocarbon layer 113 having “an alignment component value exceeding 0.2” is in a state where the alignment of the aligned object is aligned in one direction within the observation area.

Thus, in a case where it can be sufficiently confirmed that “the value of the alignment component satisfies a value of 0.2 or less” and the alignment component asymptotically approaches a constant value (S_{full}) as a result of gradually expanding the observation area, it is desirable to use an area of “d=10,000 nm” or more”, or “d=20,000 nm” or more as an observation area.

In a case where an observation area with d as large as possible is imaged, each individual CNT 42 is in an unclear state, and thus the operator needs to perform image processing for emphasizing the structure of each aligned object.

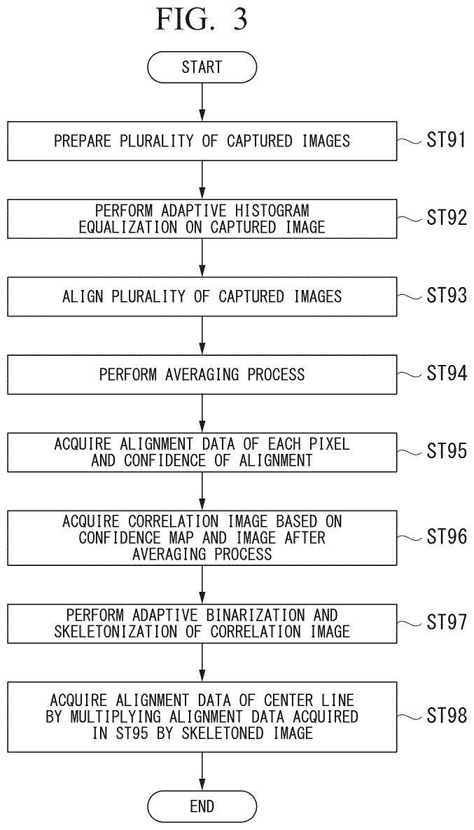

As an image processing method performed to obtain a damping constant λc contained in an aligned component, processing of a flowchart shown in FIG. 3 is performed.

First, the operator prepares a plurality of images (hereafter referred to as “AFM images”) obtained by imaging the nanocarbon layer 113 having a network by using an AFM (step ST91).

Due to the influence of noise on an image, it may be difficult to acquire alignment data from a single AFM image, and thus the operator prepares a plurality of AFM images obtained by imaging the same aligned object as necessary.

Next, the operator performs adaptive histogram equalization (contrast limited adaptive histogram equalization: CLAHE) processing on each AFM image (step ST92).

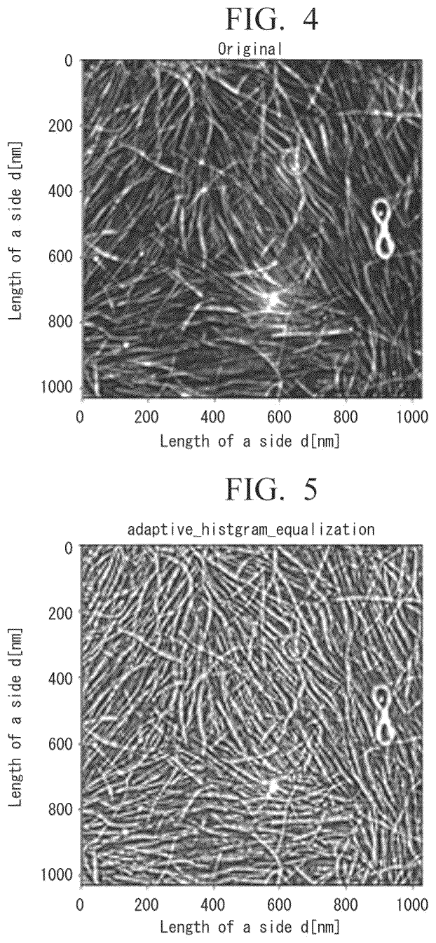

In a case where a CNT network has localized unevenness, localized brightness and darkness occur, and the structures of the respective CNTs 42 that form the CNT network may become unclear. For this reason, CLAHE processing is performed to reduce the influence of localized brightness and darkness. FIG. 4 shows an example of a captured image, and FIG. 5 shows an example of an image after histogram equalization processing.

Next, the operator aligns a plurality of captured images (step ST93).

For example, each AFM image may include a misalignment in an imaging position for each measurement, and thus, in a case where an averaging process is performed in that state, the images will appear blurred. Thus, the operator aligns the plurality of images using an algorithm such as ACCELERATED-KAZE before the averaging process.

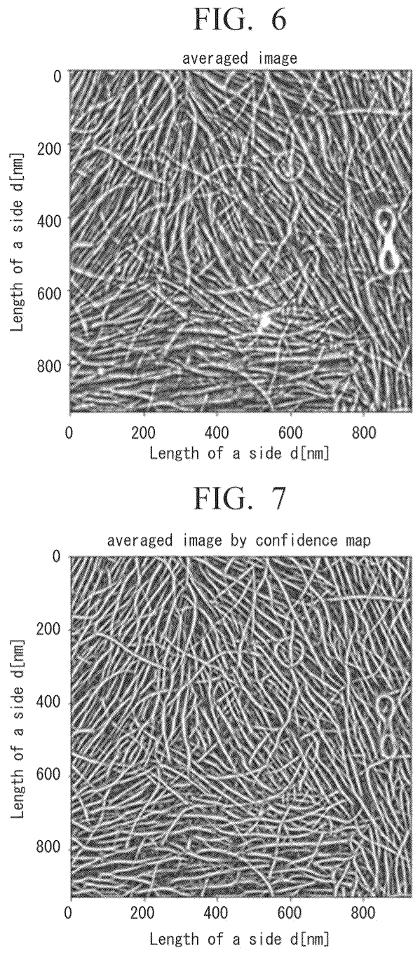

Next, the operator performs an averaging process on the plurality of aligned captured images to reduce noise (step ST94). FIG. 6 shows an example of an image after the averaging process.

Next, the operator performs a Gabor filter process on the noise-reduced image having been subjected to the averaging process to acquire alignment data θ^{˜} of each pixel shown in Formula (4) and a confidence w of the alignment shown in Formula (8) (step ST95).

$$\tilde{θ} ( x , y ) = arg {max}_{θ} ( F ( x , y , θ ) ) = arg {max}_{θ} ( ( {K}_{θ} * I ) ( x , y ) ) \qquad ( 4 )$$

$${K}_{θ} ( u , v ) = exp ( - \frac{{\tilde{u}}^{2} + {\tilde{v}}^{2}}{2 {σ}^{2}} ) cos ( \frac{2 π \tilde{u}}{λ} ) \qquad ( 5 )$$

In Formula (4), I, which is the final input to an argmax function, is a noise-reduced AFM image having been subjected to an averaging process, and K_{θ}(u,v) is the Gabor filter kernel. The Gabor filter kernel is a filter kernel that responds to a structure aligned at an angle θ.

In Formula (5), (u,v) are the local coordinates of a gabor filter, and (u^{˜},v^{˜}), which are input to the right-hand side, are the local coordinates rotated by an angle θ. A on the right-hand side represents the frequency of a cosine function, and the larger λ is, the thinner the kernel becomes.

$$V ( x , y , \tilde{θ} ) = {\int }_{- \frac{π}{2}}^{\frac{π}{2}} {d}_{a n g l e} ( \tilde{θ} ( x , y ) , θ ) {\{ F ( x , y , \tilde{θ} ( x , y ) ) - F ( x , y , θ ) \}}^{2} d θ \qquad ( 6 )$$

$${d}_{a n g l e} ( {θ}_{1} - {θ}_{2} ) = min \{ \vert {θ}_{1} - {θ}_{2} \vert , \vert {θ}_{1} - {θ}_{2} - π \vert , \vert {θ}_{1} - {θ}_{2} + π \vert \} \qquad ( 7 )$$

$$w ( x , y , \tilde{θ} ) = \sqrt{V ( x , y , \tilde{θ} )} \qquad ( 8 )$$

In a case where a similar response is obtained at angles other than a direction in which the filter responds most strongly (alignment data θ^{˜}) (case a), a squared term in an integrand function will have a small value as can be seen from Formula (6).

On the other hand, in a case where the response is small at angles other than the direction in which the filter responds most strongly (alignment data θ^{˜}) (case b), the squared term in the integrand function will have a large value compared to the case of (a).

That is, the larger the values of V in Formula (6) and w in Formula (8), the more likely an angle evaluated by the Gabor filter kernel is.

Next, the operator acquires a correlation image on the basis of a confidence map in which the confidence w obtained by the Gabor filter process is stored for each pixel, and the image after the averaging process (step ST96). For example, the operator performs a correlation calculation between the confidence map and the AFM image after the averaging process to acquire the correlation image. This calculation makes it possible to acquire an image in which a linear structure is emphasized as shown in FIG. 7.

Next, the operator performs adaptive binarization and skeletonization of the correlation image (step ST97).

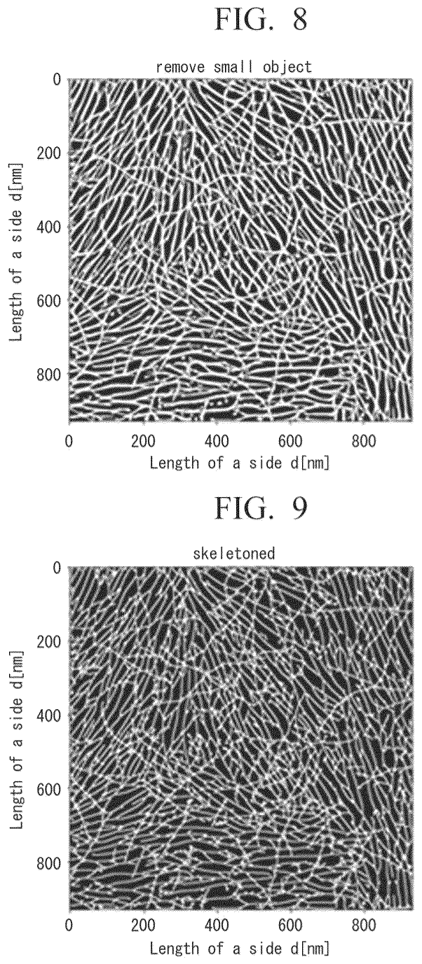

Specifically, the operator converts the correlation image acquired in step ST96 into a binarized image by adaptive threshold processing. In addition, the operator may delete small areas from FIG. 7 as necessary, as shown in FIG. 8. Thereafter, the operator performs skeletonization to reduce the influence of a line thickness of a two-dimensional structure, as shown in FIG. 9.

Next, the operator acquires alignment data of a center line by multiplying the alignment data acquired in step ST95 by a skeletoned image (step ST98).

Through the above process, alignment data of a two-dimensional structure is obtained in units of one pixel. In a case where an alignment angle and an average alignment direction n of each aligned object are derived from the alignment data acquired in step ST95 or the alignment data of the center line, an alignment parameter S_{2D}(d) (Formula (1)) is obtained from a captured image. Thereafter, a damping constant λ_{c} is determined on the basis of a relationship between an alignment component shown in Formula (3) and the size of an observation area, which is defined by a size d of one side of a square observation area.

As described above, in a case where it can be sufficiently confirmed that “the value of the alignment component satisfies a value of 0.2” or less and the alignment component asymptotically approaches a constant value (S_{full}) as a result of gradually expanding the observation area, it is desirable to use an area of “d=10,000 nm” or more or “d=20,000 nm” or more as an observation area.

### (Film Manufacturing Method)

An example of a film manufacturing method for the laminated structure 11 will be described.

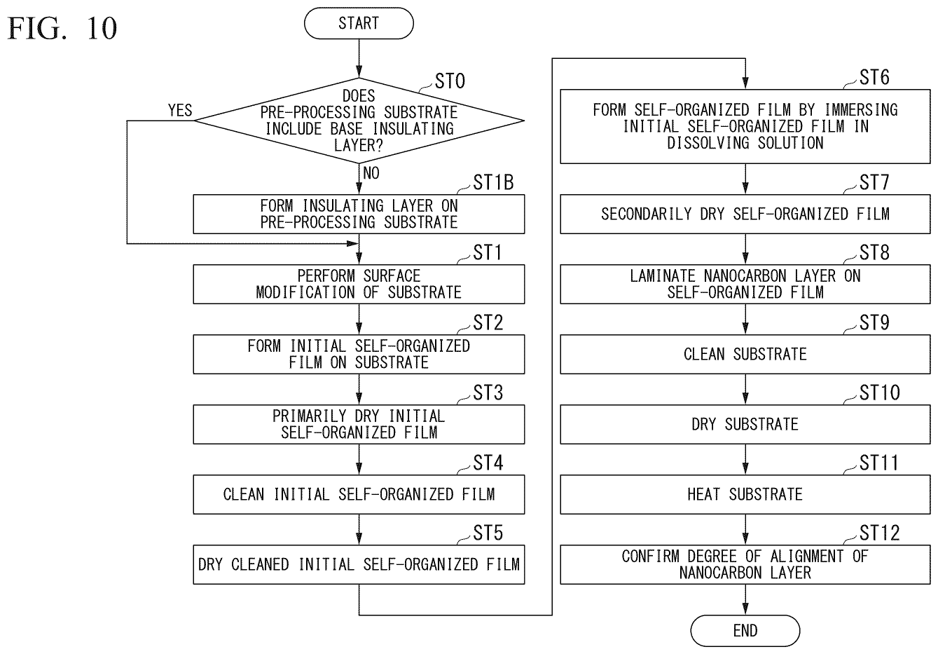

The film manufacturing method in this disclosure is performed according to a flow shown in FIG. 10.

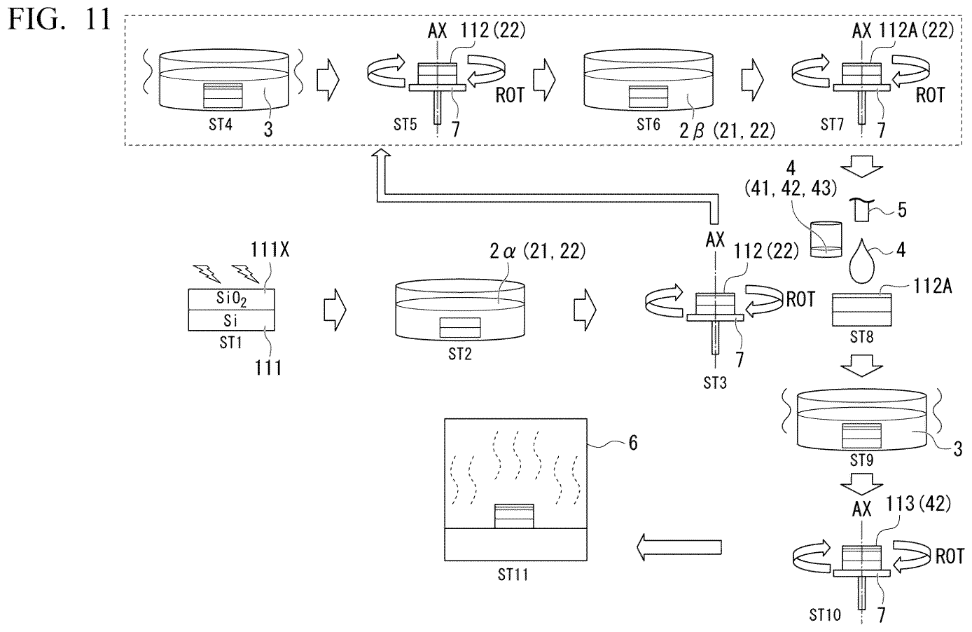

Supplementary drawings for each flow are also shown in FIG. 11.

First, an operator determines whether a pre-processing substrate includes an insulating layer (step ST0).

In a case where the pre-processing substrate does not include an insulating layer (step ST0: NO), the operator forms the base insulating layer 111X on the pre-processing substrate to form the substrate 111 (step ST1B).

There are two methods of forming the base insulating layer 111X, that is, a method of performing heat treatment on the pre-processing substrate and a method of directly forming the base insulating layer by a chemical vapor deposition (CVD) method.

In a case where the pre-processing substrate includes an insulating layer (step ST0: YES), the operator uses the pre-processing substrate as it is as the substrate 111 and performs the process of the next step ST1.

Next, the operator performs surface modification of the substrate 111 (step ST1).

Specifically, the operator performs ashing or ozone cleaning on the lamination surface 111L.

For example, in a case where the base insulating layer 111X is made of silicon oxide, hydroxyl groups are formed on the lamination surface 111L in step ST1.

Next, the operator forms an initial self-organized film (a first self-organized film, hereinafter referred to as an “initial self-organized film 112”), which accounts for the majority of the self-organized film 112A, on the substrate 111 (step ST2).

Specifically, the operator immerses the substrate 111 in a dissolving solution 2α shown in FIG. 11 for a predetermined period of time, and forms the initial self-organized film 112 on the lamination surface 111L.

The formed initial self-organized film 112 contains a silane coupling agent 22 for forming the nanocarbon layer 113 on the substrate 111.

### (Dissolving Solution)

In the dissolving solution 2α (2β) shown in FIG. 11, the silane coupling agent 22 is dissolved in a dispersion medium 21.

For example, the dissolving solution 2α and the dissolving solution 2β differ in the concentration of the silane coupling agent 22 in the dissolving solution 2.

For example, the concentration of the silane coupling agent 22 in the dissolving solution 2α is 0.01% to 0.1%.

For example, the concentration of the silane coupling agent 22 in dissolving solution 2β is 0.025% to 5%.

For example, the dispersion medium 21 is pure water, ethanol, an organic solvent such as toluene.

Examples of the silane coupling agent 22 include 3-aminopropyltriethoxysilane (APTES), 3-aminopropyltrimethoxysilane, 3-aminopropylmethyltriethoxysilane, 3-aminopropylmethyltrimethoxysilane, and the like.

For example, the operator may use a silane coupling agent 22 having an amino group to improve the adhesion of CNTs 42, which will be described below.

Next, the operator primarily dries the formed initial self-organized film 112 (step ST3).

For example, the operator may use a spin coater 7 to dry the initial self-organized film 112 (primary drying).

Specifically, the operator takes out the immersed substrate 111, and then rotates the substrate 111 with the spin coater 7 to dry the initial self-organized film 112 (primary drying).

As shown in FIG. 11, the substrate 111 rotates in one direction (ROT direction) around a rotation axis AX with the spin coater 7.

Next, the operator cleans the primarily dried initial self-organized film 112 with a cleaning solution 3 (step ST4).

For example, pure water or ultrapure water may be used as the cleaning solution 3.

Specifically, the operator cleans the substrate 111 with ultrapure water. For example, the operator may use ultrasonic waves to clean the substrate 111.

By cleaning, the operator separates bonds with weak bonding strength, such as Van der Waals forces, between the substrate 111 and the initial self-organized film 112.

Step ST4 may not be performed in a case where the amount of silane coupling agent 22 attached to the primarily dried initial self-organized film 112 is sufficiently smaller than the amount of silane coupling agent 22 contained in the dissolving solution 2β to be described below in step ST6. The same applies to step ST5, which is post-processing of step ST4.

Next, the operator dries the initial self-organized film 112 after the cleaning (step ST5).

For example, the operator performs the same drying process as in step ST3. The rotation speed of the spin coater may be adjusted appropriately for each step.

Next, as shown in FIG. 11, the operator immerses the initial self-organized film 112 formed on the substrate 111 in the dissolving solution 2B in which the silane coupling agent 22 has been dissolved, thereby forming a self-organized film (a second self-organized film) 112A (step ST6).

In a case where steps ST4 and ST5 have been performed, the operator immerses the cleaned initial self-organized film 112 in the dissolving solution 2B as the dried (primarily dried) initial self-organized film 112 in step ST6.

After the immersion, the amount of the initial self-organized film 112 formed on the lamination surface 111L is adjusted, thereby forming the self-organized film 112A. That is, the amount of the silane coupling agent 22 contained in the self-organized film 112A is changed by step ST6 compared to the initial self-organized film 112 formed by step ST2.

The degree of alignment of the self-organized film 112A changes depending on the amount of the silane coupling agent. In other words, the degree of alignment of the self-organized film 112A is controlled by adjusting the concentration of the dissolving solution 2β. Thereby, the degree of local alignment of the nanocarbons contained in the nanocarbon layer 113 is suppressed.

Next, the operator dries (secondarily dries) the self-organized film 112A formed on the substrate 111 after immersion in the dissolving solution 2β (step ST7).

For example, the operator performs the same drying process as in steps ST3 and ST5. The rotation speed of the spin coater may be adjusted appropriately for each step.

For example, in step ST7, the self-organized film 112A is dried by the spin coater at a rotation speed of 1000 rpm or more and 4000 rpm or less.

Next, the operator laminates the nanocarbon layer 113 on the dried (secondarily dried) self-organized film 112A (step ST8).

Specifically, the operator drops a dispersion liquid 4 onto the self-organized film 112A from a nozzle 5 and leaves it for a predetermined period of time. Thereby, the nanocarbon layer 113 is laminated.

For example, the nozzle 5 is included in a dispenser, an inkjet, or the like.

### (Dispersion Liquid)

The dispersion liquid 4 includes a dispersion medium 41, CNTs 42, and a surfactant 43. For example, ultrasonic treatment is used for mixing in a case of preparing the dispersion liquid 4.

For example, the dispersion liquid 4 contains the CNTs 42 with a concentration of 0.001% to 0.3% by mass and the surfactant 43 with a concentration of 0.01% to 1% by mass.

The operator can sufficiently disperse the CNTs 42 in the dispersion liquid 4 by using the surfactant 43 in a case of laminating the nanocarbon layer 113. The surfactant 43 may be non-ionic. A non-ionic surfactant is more easily removed by heat treatment or the like than an ionic surfactant.

For example, a non-ionic surfactant is a polyoxyethylene alkyl ether solution such as polyoxyethylene (100) stearyl ether or polyoxyethylene (23) lauryl ether.

The dispersion medium 41 is not particularly limited as long as it is a solvent that can disperse and suspend the CNTs 42 in the dispersion liquid 4, and can be, for example, water, heavy water, an organic solvent, an ionic liquid, or a mixture of these.

The operator can sufficiently separate aggregated metallic CNTs and semiconducting CNTs by performing ultrasonic treatment on the mixture of the dispersion liquid 4.

In addition, the operator can appropriately control the length of the CNT 42 by controlling the output of ultrasonic waves a treatment time in the ultrasonic treatment.

For example, the operator may separate and remove the metallic CNTs and semiconducting CNTs, which have not been dispersed by the ultrasonic treatment, by ultracentrifugation. For example, the operator may remove those that are not useful for the electrical properties of a borometer to be manufactured, such as CNT bundles and amorphous carbon contained in the dispersion liquid 4, in ultracentrifugation.

For example, a dispersion liquid in which the surfactant 43, the metallic CNTs, and the semiconducting CNTs are uniformly dispersed in the dispersion medium 41 can be used as the dispersion liquid 4.

For example, the semiconducting CNTs may be separated or concentrated and used to obtain a high TCR in the borometer.

Next, the operator cleans the substrate 111 on which the nanocarbon layer 113 is laminated with the cleaning solution 3 (step ST9).

For example, pure water or ultrapure water may be used as the cleaning solution 3.

Specifically, the operator cleans the substrate 111 with ultrapure water. For example, the operator may use ultrasonic waves to clean the substrate 111.

Next, the operator dries the cleaned substrate 111 (step ST10).

For example, the operator performs the same drying process as in steps ST3, ST5, and ST7. The rotation speed of the spin coater may be adjusted appropriately for each step.

Next, the operator heats the dried substrate 111 (step ST11).

Specifically, the operator places the substrate 111 in a chamber 6 and heats it in an environment at 180° C. for 2 hours. Through these operations, the nanocarbon layer 113 in which the degree of local alignment of the nanocarbons is suppressed is formed on the substrate 111.

The operator may also additionally heat the substrate 111 in an environment at 300° C. to 400° C. to remove surfactant components that may inhibit electrical conduction.

Next, the operator confirms the degree of alignment of the nanocarbon layer 113 (step ST12).

For example, the operator confirms the degree of alignment of the nanocarbon layer 113 by using the damping constant λ_{c} described above (End).

### (Actions and Effects)

According to the film manufacturing method of this disclosure, the initial self-organized film 112 is immersed in the dissolving solution 2β containing the silane coupling agent 22. Thereby, it is possible to adjust the amount of the initial self-organized film 112 and control the alignment of the self-organized film 112A.

That is, the operator can control the alignment of the organic molecules contained in the self-organized film 112A and control the degree of alignment of the nanocarbon layer 113 laminated on the substrate 111 via the self-organized film 112A.

Thus, the film manufacturing method of this disclosure makes it easy to control the degree of alignment.

Furthermore, the film manufacturing method of this disclosure can separate bonds with weak bonding strength, such as Van der Waals forces, between the substrate 111 and the initial self-organized film 112 by cleaning the dried (primarily dried) initial self-organized film 112. This makes it easier to adjust the amount of the initial self-organized film 112, and has the effect of making it easier to control the alignment of the self-organized film 112A.

In addition, the film manufacturing method of this disclosure “includes a step of forming a self-organized film (initial self-organized film 112) on a substrate (step ST2), a step of drying the self-organized film (initial self-organized film 112) (step ST3), a step of cleaning the self-organized film (initial self-organized film 112) using the cleaning solution 3 (step ST4), a step of drying the self-organized film (initial self-organized film 112) after cleaning (step ST5), a step of immersing the substrate 111 in the dissolving solution 2β in which the silane coupling agent 22 has been dissolved (step ST6), a step of drying the substrate 111 after immersion in the dissolving solution 2β (step ST7), and a step of laminating a nanocarbon layer on the self-organized film 112A (step ST8)”, and thus the following effect can be obtained.

By these steps, the operator can control the alignment of the organic molecules contained in the self-organized film 112A and control the degree of alignment of the nanocarbon layer 113 laminated on the substrate 111 via the self-organized film 112A.

Thus, it is possible to obtain the effect that “the film manufacturing method according to this disclosure makes it easy to control the degree of alignment”.

Further, in the film manufacturing method of this disclosure, in addition to the effect that “it is possible to strengthen the bond with CNTs by a silanol group of the silane coupling agent 22” by “the silane coupling agent 22 having an amino group”, it is also possible to obtain the effect that “the self-organized film 112A can strengthen the bond with the substrate 111”. For example, in a case where the base insulating layer 111X is made of SiO₂, it is also possible to obtain the effect that “the bond becomes stronger”.

Further, in the film manufacturing method of this disclosure, it is also possible to obtain the effect that “it is possible to further strengthen the bond with CNTs in the silane coupling agent 22” by “the silane coupling agent 22 which is 3-aminopropyltriethoxysilane”

Further, in the film manufacturing method of this disclosure, it is also possible to obtain the effect that “it is easier to control the degree of alignment of the nanocarbon layer 113 laminated on the substrate 111” by “the concentration of the silane coupling agent 22 in the dissolving solution 2β which is 0.025% to 5%”.

Further, in the film manufacturing method of this disclosure, it is also possible to obtain the effect that “it is easier to form a network structure of the carbon nanotubes and it easier to reduce the resistance of the laminated structure 11” by “the nanocarbon layer containing carbon nanotubes”.

Further, in the film manufacturing method of this disclosure, it is also possible to obtain the effect that “the dispersibility of the CNTs 42 is improved, CNTs 42 are less likely to aggregate, and it is easier to control the degree of alignment of the nanocarbon layer 113 laminated on the substrate 111 via the self-organized film 112A” by “the nanocarbon layer 113 which is laminated using the surfactant 43”.

In the laminated structure 11 of this disclosure, “the laminated structure 11 includes, in order, the substrate 111, the self-organized film 112A, and the nanocarbon layer 113 having an alignment parameter, the alignment parameter has an alignment component and a random component, the alignment component is expressed by Formula (3) which is a function of the damping constant λ_{c} related to the degree of local alignment, the size d of one side of the square observation area of the nanocarbon layer 113, and the constant value S_{full}, and the damping constant λ_{c} is 300 nm or more”, and thus the following effect can be obtained.

$${S}_{2 D}^{a l i g n} ( d ) = {S}_{full} + ( 1 - {S}_{full} ) {e}^{- \frac{d}{2 {λ}_{c}}} \qquad ( 3 )$$

That is, the alignment of the network structure of the nanocarbon layer 113 laminated on the substrate 111 via the self-organized film 112A can be selected to a predetermined degree of alignment using the damping constant λ_{c}. Thereby, it is possible to obtain the laminated structure 11 with a degree of alignment controlled by the self-organized film 112A having a specific amount.

Thus, it is possible to obtain the effect that “the laminated structure 11 according to this disclosure makes it easy to control the degree of alignment”.

In addition, since the alignment of the network structure affects the electrical resistance, it is possible to associate the alignment of the network structure with the electrical resistance via the damping constant λ_{c} by quantitatively grasping the alignment of the network structure, and it is also possible to evaluate the overall resistance value of the network structure.

Further, in the laminated structure 11 of this disclosure, it is also possible to obtain the effect that “the alignment component asymptotically approaches the constant value S_{full} as the observation area becomes larger,” and therefore, “the alignment component exponentially attenuates by gradually expanding the observation area, making it easy to grasp that the degree of alignment is controlled by the damping constant λ_{c}”.

In the laminated structure 11 disclosed above, the substrate 111 is a Si substrate, but may be an insulating material. Thereby, the disclosure can also be applied to elements such as borometers having diaphragms.

In the laminated structure 11 disclosed above, the nanocarbon layer 113 contains CNTs, but may contain CNB.

The CNB has a shape in which single-layer carbon nanophones are radially assembled and extended in a fiber form. The CNB is a nanocarbon that has both high conductivity and high dispersibility, which are characteristics of CNT and CNHs. Thereby, it is possible to control the degree of alignment of the nanocarbon layer 113 laminated on the substrate 111 through the self-organized film 112A in the same manner as in the case of the CNT 42.

In the film manufacturing method disclosed above, a material having an amino group and a silanol group may be used instead of the silane coupling agent 22 contained in the dissolving solution 2β. Even in a case where this material is used instead of the silane coupling agent 22, the amino group promotes the adhesion of the CNTs 42, and the silanol group strengthens the bond between the substrate 111 and the self-organized film 112A. Thereby, it is possible to obtain the same effect as the suppression of the degree of alignment of the nanocarbon layer 113 using the silane coupling agent 22 of this disclosure.

In the above disclosure, the alignment of organic molecules contained in the self-organized film 112A of the laminated structure 11 is controlled, and thus it is possible to control the degree of alignment of the nanocarbon layer 113 laminated on the substrate 111 via the self-organized film 112A. Thereby, it is disclosed that the laminated structure 11 disclosed above makes it easy to control the degree of alignment.

On the other hand, the borometer disclosed below includes a laminated structure 11C in a light receiving part that detects infrared rays. Borometers according to some example embodiments focus on the fact that a nanocarbon layer has a predetermined degree of alignment depending on a distance between electrodes to be connected, which makes it easier to form a network conductive path in the nanocarbon layer and makes it easier to reduce a resistance value.

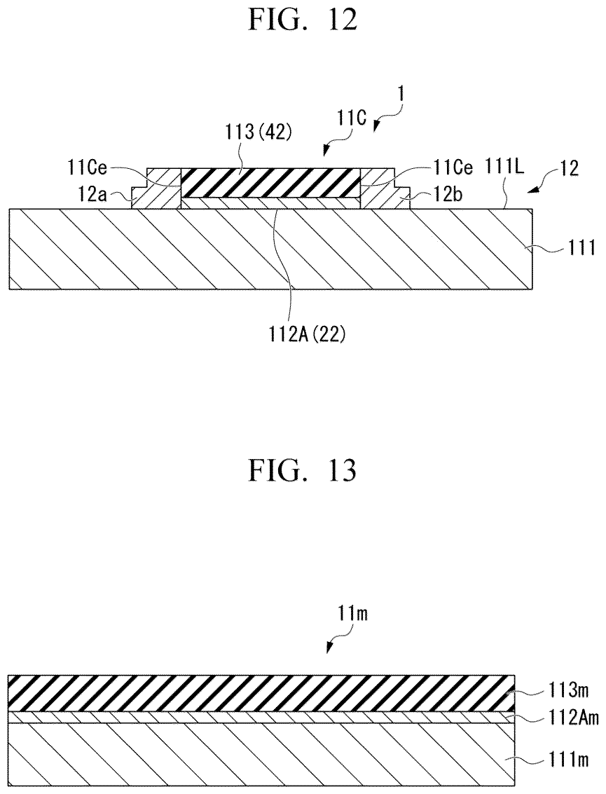

An example of the borometer in this disclosure will be described below with reference to FIG. 12.

Components common to the above disclosure will be given the same reference numerals, and detailed descriptions thereof will be omitted.

A borometer 1 is used as a sensor for detecting infrared rays.

The borometer 1 includes the laminated structure 11C and an electrode 12.

The laminated structure 11C includes, in order, a substrate 111, a self-organized film 112A in which the amount of an initial self-organized film 112 is adjusted, and a nanocarbon layer 113.

For example, the substrate 111 included in the laminated structure 11C is an insulating material.

For example, the laminated structure 11C may include the initial self-organized film 112 on a portion of a laminated surface 111L. In this case, the nanocarbon layer may be present on a portion of the substrate 111.

### (Electrode)

The electrode 12 is electrically connected to the nanocarbon layer 113.

The electrode 12 is a pair of electrodes (first electrode 12a, second electrode 12b) that sandwich the laminated structure 11C.

For example, the electrode 12 may be formed such that the pair of electrodes (first electrode 12a, second electrode 12b) that sandwich the laminated structure 11C or a part thereof, the laminated structure 11C including the substrate 111, the self-organized film 112A, and the nanocarbon layer 113 in this order.

For example, in this disclosure, the electrode 12 is formed to sandwich the self-organized film 112A and the nanocarbon layer 113, which are included in the laminated structure 11C.

The thickness of the electrode 12 can be adjusted as appropriate. For example, the thickness of the electrode 12 is 10 nm to 1.0 mm. For example, the thickness of the electrode 12 is 50 nm to 1.0 μm.

A distance between the pair of electrodes (first electrode 12a, second electrode 12b) can be adjusted as appropriate. For example, in the case of the borometer 1 including the laminated structure 11C and the pair of electrodes 12, in a case where the distance between the pair of electrodes (first electrode 12a, second electrode 12b) is small with respect to the damping constant λ_{c}, the overall resistance value of the network structure changes significantly depending on whether the alignment of the electrode 12 is parallel or perpendicular to the alignment direction of the nanocarbon layer 113, and the overall resistance value may be difficult to stabilize. On the other hand, in a case where the distance between the pair of electrodes is large with respect to the damping constant λ_{c}, the alignment direction is uniform, making it easier to stabilize the overall resistance value of the network structure. For example, the distance between the pair of electrodes (first electrode 12a, second electrode 12b) is 1.0 μm to 50 μm. For example, the distance between the pair of electrodes (first electrode 12a, second electrode 12b) is 5.0 μm to 20 μm.

For example, the electrode 12 is an electrode using Au, Al, Ti, or an alloy mainly containing these. Furthermore, each of the electrodes 12 (first electrode 12a, second electrode 12b) may include an underlayer for the electrode. The underlayer may be a layer containing Ti. As an example, the electrode 12 of this disclosure is an electrode in which an Au layer is laminated via a Ti layer as an underlayer.

### (Actions and Effects)

According to some of the example embodiments, the degree of alignment of the nanocarbon layer 113 laminated on the substrate 111 can be controlled via the self-organized film 112A by controlling the alignment of the organic molecules contained in the self-organized film 112A of the laminated structure 11C.

Thus, the laminated structure 11C according to this disclosure makes it easy to control the degree of alignment.

In addition, the nanocarbon layer has a predetermined degree of alignment in accordance with a distance between electrodes to be connected, which makes it easier to form a network conductive path in the nanocarbon layer and makes it easier to reduce a resistance value.

In the borometer 1 disclosed above, the laminated structure 11C may include a laminated end surface 11Ce at which the nanocarbon layer 113 is cut out. As an example, it is considered that the laminated end surface 11Ce from a part of the substrate 111 to the nanocarbon layer 113 is cut out by an etching process or the like. As another example, the laminated end surface 11Ce from the self-organized film 112A to the nanocarbon layer 113 may be cut out. In a case of performing the etching process, a protective layer for preventing damage due to the etching may be formed on the nanocarbon layer 113.

After the cut-out, the electrode 12 may be electrically connected to the nanocarbon layer 113 exposed at the cut-out laminated end surface 11Ce.

An example of the configuration of the laminated structure in this disclosure will be described below with reference to FIG. 13.

### (Configuration)

A laminated structure 11m includes, in order, a substrate 111m, a self-organized film 112Am, and a nanocarbon layer 113m having an alignment parameter. The alignment parameter has an alignment component and a random component, and the alignment component is expressed by Formula (3) which is a function of a damping constant λ_{c} related to the degree of local alignment, a size d of one side of a square observation area of the nanocarbon layer 113m, and a constant value S_{full}, and the damping constant λ_{c} is 300 nm or more.

$${S}_{2 D}^{a l i g n} ( d ) = {S}_{full} + ( 1 - {S}_{full} ) {e}^{- \frac{d}{2 {λ}_{c}}} \qquad ( 3 )$$

### (Actions and Effects)

According to the laminated structure 11m of this disclosure, the alignment of the network structure of the nanocarbon layer 113m laminated on the substrate 111m via the self-organized film 112Am can be selected to a predetermined degree of alignment using the damping constant λ_{c}. Thereby, is possible to obtain the laminated structure 11m with a degree of alignment controlled by the self-organized film 112Am having a specific amount.

Thus, the laminated structure 11m of this disclosure makes it easy to control the degree of alignment.

In addition, since the alignment of the network structure affects the electrical resistance, it is possible to associate the alignment of the network structure with the electrical resistance via the damping constant λ_{c} by quantitatively grasping the alignment of the network structure, and it is also possible to evaluate the overall resistance value of the network structure.

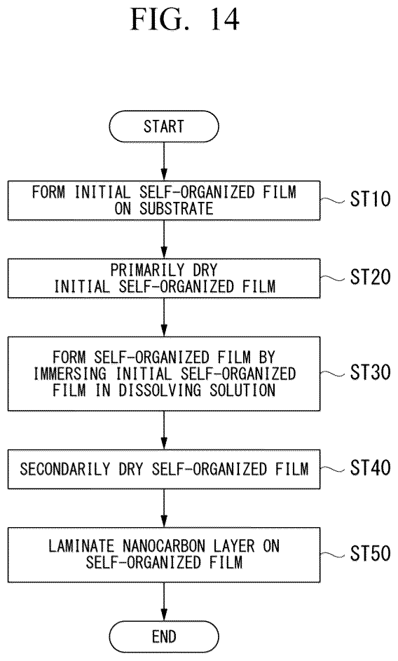

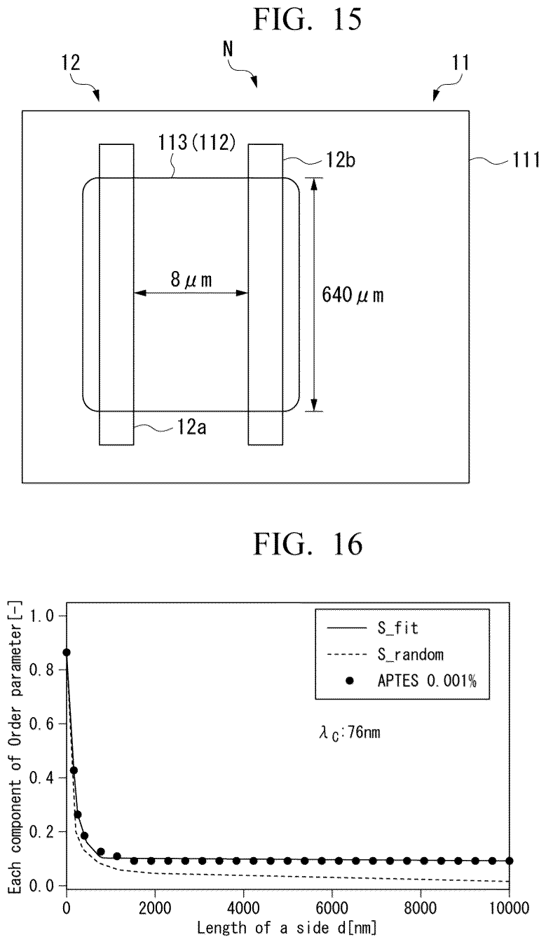

Hereinafter, an example of the film manufacturing method in this disclosure will be described with reference to FIG. 14.

The film manufacturing method in this disclosure is performed in accordance with a flow shown in FIG. 14.

The film manufacturing method includes a step of forming an initial self-organized film on a substrate (step ST10), a step of primarily drying the formed initial self-organized film (step ST20), a step of forming a self-organized film by immersing the primarily dried initial self-organized film in a dissolving solution in which a silane coupling agent is dissolved (step ST30), a step of secondarily drying the formed self-organized film (step ST40), and a step of laminating a nanocarbon layer on the secondarily dried self-organized film (step ST50).

### (Action and Effect)

According to the film manufacturing method of this disclosure, it is possible to control the alignment of the self-organized film by immersing the self-organized film in a dissolving solution containing a silane coupling agent.

That is, the operator can control the alignment of the organic molecules contained in the self-organized film and control the degree of alignment of the nanocarbon layer laminated on the substrate via the self-organized film.

Thus, the film manufacturing method of this disclosure makes it easy to control the degree of alignment.

### Example

The effects of this disclosure will be described in more detail below with reference to an example. The conditions in the example are one example of conditions adopted to confirm the feasibility and effects of this disclosure, and this disclosure is not limited to this example of conditions. This disclosure may adopt various conditions as long as the object of this disclosure is achieved without departing from the gist of this disclosure.

Approximately 16 elements N (N=I−V) to be evaluated were created for each of elements I to V using the film manufacturing method disclosed above.

The element N included a laminated structure 11 and a new pair of electrodes 12.

The element N included a base insulating layer and includes an initial self-organized film 112 on a part of the substrate 111. The nanocarbon layer 113 was located on a part of the substrate 111.

A distance between the pair of electrodes (first electrode 12a, second electrode 12b) was 8 μm, and CNTs 42 contained in the nanocarbon layer 113 electrically connected the electrodes over 640 μm in the longitudinal direction of the electrode 12. In a case where the elements N were created, the concentration of a silane coupling agent 22 in a dissolving solution 2α was 0.01% to 0.1%.

In a case where the elements N were created, the concentration of a silane coupling agent 22 in a dissolving solution 2β was 0.001% to 5%.

In a case where the elements N were created, a dispersion liquid 4 contained CNTs 42 at a concentration of 0.001% to 0.3% by mass and a surfactant 43 at a concentration of 0.01% to 1% by mass.

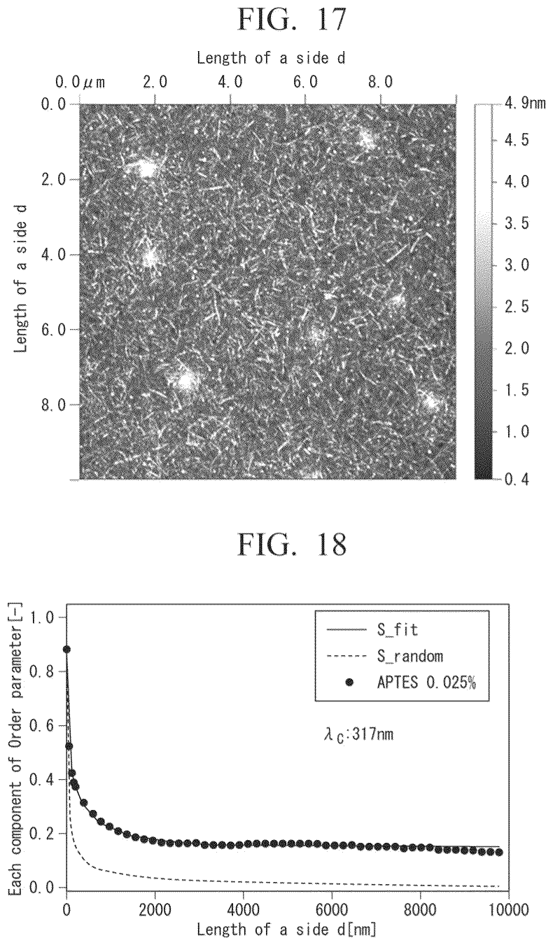

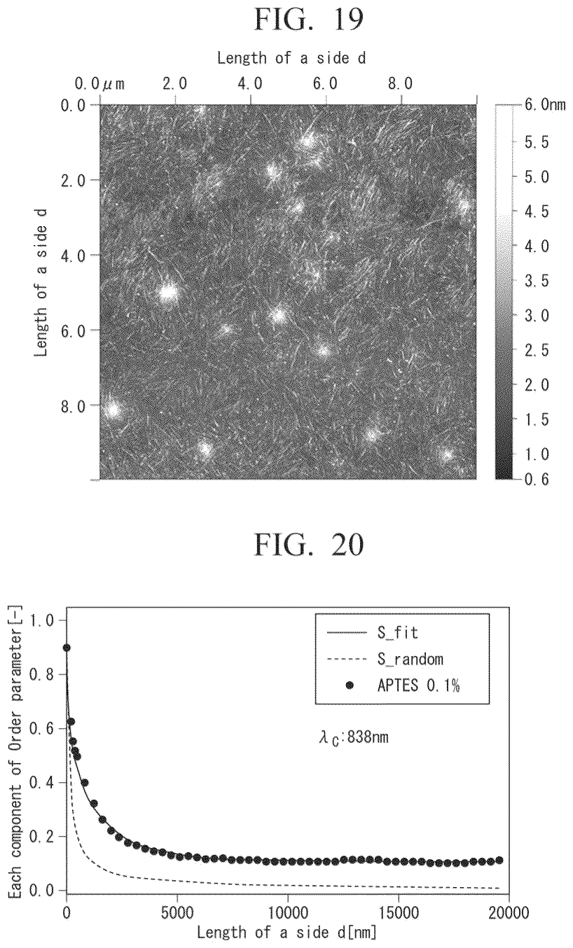

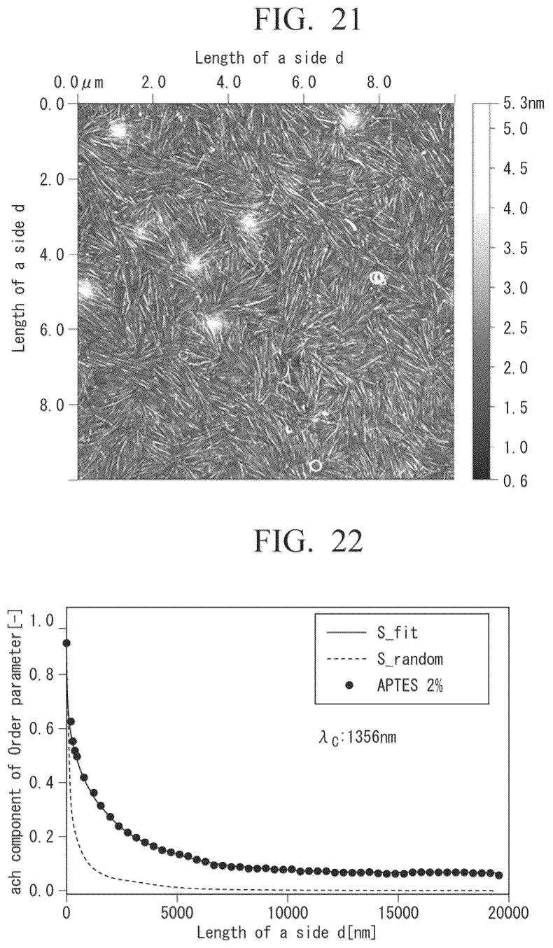

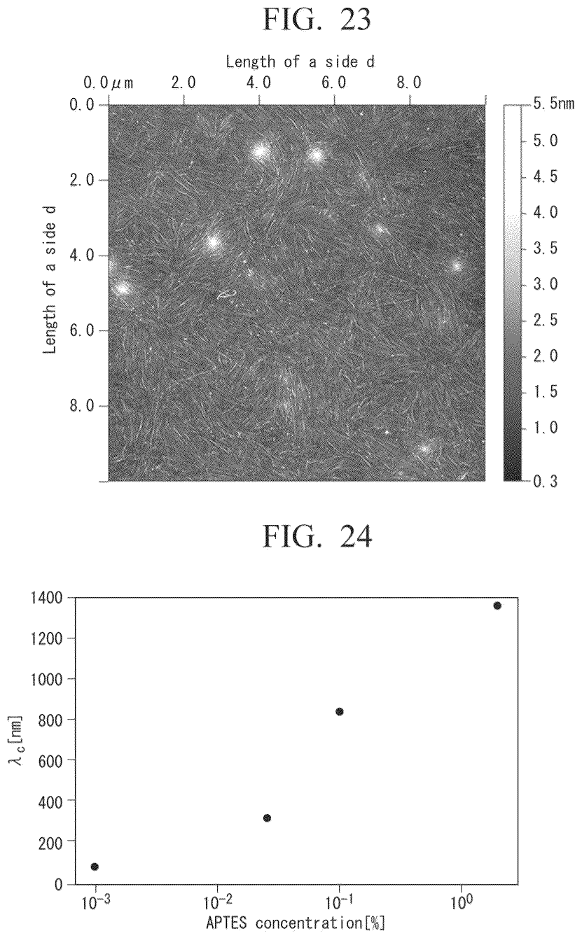

The concentration of the silane coupling agent 22 (APTTES) in the dissolving solution 2β was as follows. The concentration of APTES used to create the element I in FIGS. 16 and 17 was 0.001%. The concentration of APTES used to create the element II in FIGS. 18 and 19 was 0.025%. The concentration of APTES used to create the element III in FIGS. 20 and 21 was 0.1%. The concentration of APTES used to create the element IV in FIG. 22 was 2.0%. The concentration of APTES used to create the element V in FIG. 23 was 0.05%.

A vertical axis represents the value of each component (alignment component and random component) of an alignment parameter, and a horizontal axis represents the size of an observation area which is defined by a size d of one side of a square observation area. As described above, the alignment parameter is expressed as the sum of two components, that is, the alignment component and the random component, and thus a comparison was made between the components of the alignment parameter.

In each of FIGS. 16, 18, 20, and 22, it was confirmed that the value of an alignment component (S_fit) asymptotically approaches a constant value (S_{full}) in an observation area where “the value of an alignment component is 0.2” or less. As for a random component (S_random), it was confirmed that an alignment component in each observation area exponentially attenuated as a whole and the degree of attenuation was similar regardless of the concentration of APTES. For this reason, it was estimated that an index of the degree of alignment could be obtained by observing the tendency of attenuation of the alignment component in the alignment parameter.

FIG. 24 shows a relationship between the concentration of APTES and a damping constant λ_{c}, and it was confirmed that the higher the concentration of APTES, the greater the damping constant λ_{c}. It was also confirmed that the damping constant λ_{c} becomes even larger at an APTES concentration of 5% in the dissolving solution 2β. Thus, it was shown that & obtained in this disclosure can be used as a quantitative index of the degree of alignment.

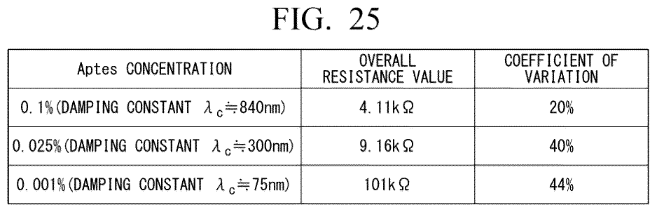

From AFM images of four CNT networks shown in FIGS. 17, 19, 21, and 23, it could be seen that the alignment of local CNTs is eliminated as the concentration of APTES becomes lower. FIG. 25 was a diagram showing comparison between the overall resistance values of the CNT network in the element N. It was confirmed that the overall resistance value decreased as the damping constant λ_{c} increased. A coefficient of variation was obtained by dividing a standard deviation of the overall resistance value in each of the 16 elements N created by an average of the overall resistance value. Although the coefficient of variation remained relatively high from the APTES concentration of 0.001% used to create the element I to the APTES concentration of 0.025% used to create the element II, the overall resistance value decreased by an order of magnitude as the APTES concentration increases, and thus it was confirmed that a laminated structure having a CNT network with a damping constant λ_{c} of 300 nm or more was desirable.

A film manufacturing method, laminated structure, and borometer according to this disclosure make it easy to control the degree of alignment.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with other example embodiments.

Some or all of the above-described example embodiments can be described as the following supplementary notes, but are not limited to the following supplementary notes.

### (Supplementary Note 1)

A film manufacturing method including:
forming a first self-organized film on a substrate;
drying the formed first self-organized film;
immersing the dried first self-organized film in a dissolving solution in which a silane coupling agent is dissolved to form a second self-organized film;
drying the formed second self-organized film; and
laminating a nanocarbon layer on the dried second self-organized film.

### (Supplementary Note 2)

The film manufacturing method according to supplementary note 1, further including:

cleaning the dried first self-organized film before the immersing.

### (Supplementary Note 3)

The film manufacturing method according to supplementary note 1 or 2, wherein the silane coupling agent includes an amino group.

### (Supplementary Note 4)

The film manufacturing method according to any one of supplementary notes 1 to 3, wherein the silane coupling agent is 3-aminopropyltriethoxysilane.

### (Supplementary Note 5)

The film manufacturing method according to any one of supplementary notes 1 to 4, wherein a concentration of the silane coupling agent in the dissolving solution is 0.025% to 5% by mass.

### (Supplementary Note 6)

The film manufacturing method according to any one of supplementary notes 1 to 5, wherein the nanocarbon layer includes carbon nanotubes.

### (Supplementary Note 7)

The film manufacturing method according to any one of supplementary notes 1 to 6, wherein the nanocarbon layer is laminated on the dried second self-organized film using a surfactant.

### (Supplementary Note 8)

A laminated structure including, in order, a substrate, a self-organized film, and a nanocarbon layer having an alignment parameter, wherein
the alignment parameter has an alignment component and a random component,
a function of the alignment component is expressed by a formula,

$${S}_{2 D}^{a l i g n} ( d ) = {S}_{full} + ( 1 - {S}_{full} ) {e}^{- \frac{d}{2 {λ}_{c}}}$$

wherein λ_{c} is a damping constant related to the degree of local alignment, d is a size of one side of a square observation area of the nanocarbon layer, and S_{full} is a constant value, and
the damping constant is 300 nm or more.

### (Supplementary Note 9)

The laminated structure according to supplementary note 8, wherein the alignment component asymptotically is configured to approach the constant value as the observation area becomes larger.

### (Supplementary Note 10)

The laminated structure according to supplementary note 8 or 9, wherein the nanocarbon layer contains carbon nanotubes.

### (Supplementary Note 11)

A borometer including:
the laminated structure according to any one of supplementary notes 8 to 10; and
an electrode electrically connected to the nanocarbon layer.

What is claimed is:

1. A film manufacturing method comprising:
forming a first self-organized film on a substrate;
drying the formed first self-organized film;
immersing the dried first self-organized film in a dissolving solution in which a silane coupling agent is dissolved to form a second self-organized film;
drying the formed second self-organized film; and
laminating a nanocarbon layer on the dried second self-organized film.

2. The film manufacturing method according to claim 1, further comprising:
cleaning the dried first self-organized film before the immersing.

3. The film manufacturing method according to claim 1, wherein the silane coupling agent includes an amino group.

4. The film manufacturing method according to claim 1, wherein the silane coupling agent is 3-aminopropyltriethoxysilane.

5. The film manufacturing method according to claim 1, wherein a concentration of the silane coupling agent in the dissolving solution is 0.025% to 5% by mass.

6. The film manufacturing method according to claim 1, wherein the nanocarbon layer includes carbon nanotubes.

7. The film manufacturing method according to claim 1, wherein the nanocarbon layer is laminated on the dried second self-organized film using a surfactant.

8. A laminated structure including, in order, a substrate, a self-organized film, and a nanocarbon layer having an alignment parameter, wherein
the alignment parameter has an alignment component and a random component,
a function of the alignment component is expressed by a formula:
$${S}_{2 D}^{a l i g n} ( d ) = {S}_{full} + ( 1 - {S}_{full} ) {e}^{- \frac{d}{2 {λ}_{c}}} ,$$
wherein λ_{c} is a damping constant related to the degree of local alignment, d is a size of one side of a square observation area of the nanocarbon layer, and S_{full} is a constant value, and
the damping constant is 300 nm or more.

9. The laminated structure according to claim 8, wherein the alignment component asymptotically is configured to approach the constant value as the observation area becomes larger.

10. The laminated structure according to claim 8, wherein the nanocarbon layer contains carbon nanotubes.

11. A bolometer comprising:
the laminated structure according to claim 8; and
an electrode electrically connected to the nanocarbon layer.
